(19) United States
(12) Patent Application Publication
(10) Pub. No.: US 2011/0126900 A1
(43) Pub. Date: Jun. 2, 2011

(54) Dye-sensitized solar cell electrode and dye-sensitized solar cell

(75) Inventors: Shinichi Inoue, Osaka (JP); Hiroyuki Hanazono, Osaka (JP)

(73) Assignee: Nitto Denko Corporation, Osaka (JP)

(21) Appl. No.: 12/926,429

(22) Filed: Nov. 17, 2010

(30) Foreign Application Priority Data
Dec. 1, 2009 (JP) 2009-273694

(51) Int. Cl. H01L 51/44; H01L 31/0224

(52) U.S. Cl. 136/256

(57) ABSTRACT

A dye-sensitized solar cell electrode includes a substrate made of a polyimide film obtained by reaction of a biphenyl tetracarboxylic acid dianhydride compound with a paraphenylenediamine compound.

### CROSS-REFERENCE TO RELATED APPLICATION

The present application claims priority from Japanese Patent Application No. 2009-273694 filed on Dec. 1, 2009, the content of which is hereby incorporated by reference into this application.

### BACKGROUND OF THE INVENTION

1. Field of the Invention

The present invention relates to a dye-sensitized solar cell electrode and a dye-sensitized solar cell. In particular, the present invention relates to a dye-sensitized solar cell electrode suitably used as a counter electrode and/or a working electrode of a dye-sensitized solar cell, and to a dye-sensitized solar cell in which the dye-sensitized solar cell electrode is used.

2. Description of the Related Art

In recent years, a dye-sensitized solar cell in which a dye-sensitized semiconductor is used has been proposed as a new solar cell that may replace silicon-based solar cells in view of mass production and cost reduction.

A dye-sensitized solar cell usually has a working electrode (anode) having a photosensitizing function, an opposing electrode (counter electrode, cathode) that is disposed to face the working electrode with a space provided therebetween, and a liquid electrolyte that fills in between the two electrodes. In dye-sensitized solar cells, electrons generated in the working electrode based on sunlight irradiation migrate to the counter electrode via wirings, and the electrons are released and received in the liquid electrolyte between the two electrodes.

In such dye-sensitized solar cells, the working electrode is composed of a substrate (anode-side substrate), a transparent conductive film that is laminated onto the surface of the substrate, and a dye-sensitized semiconductor that is laminated onto the surface of the conductive film and to which dyes are adsorbed; and the opposing electrode is composed of a substrate (cathode-side substrate), a conductive film that is laminated onto the surface of the substrate, and a catalyst layer laminated onto the surface of the conductive film. The substrates of the working electrode and the counter electrode are usually formed from glass. The liquid electrolyte contains iodine.

There has been proposed that the substrates of those electrodes in dye-sensitized solar cells be formed from resin in order to achieve flexibility and a light weight. For example, there has been proposed that the substrate of the counter electrode be formed from polyethylene-2,6-naphthalate (PEN) (e.g., see Japanese Unexamined Patent Publication No. 2006-282970).

### SUMMARY OF THE INVENTION

However, in the dye-sensitized solar cell disclosed in Japanese Unexamined Patent Publication No. 2006-282970, iodine easily penetrates into the substrate under a high temperature, and therefore physical properties of the substrate are reduced, and appearance of the substrate becomes poor. As a result, disadvantages of a decrease in power generation efficiency of the dye-sensitized solar cell arise.

Additionally, it is necessary that decomposition due to iodine in the liquid electrolyte under a high temperature be prevented in the substrate of a dye-sensitized solar cell.

An object of the present invention is to provide a dye-sensitized solar cell electrode and a dye-sensitized solar cell with which flexibility and a light weight are ensured, mass production and cost reduction are achieved, liquid electrolyte penetration is prevented, and a decrease in power generation efficiency is prevented.

A dye-sensitized solar cell electrode of the present invention includes a substrate made of a polyimide film obtained by reaction of a biphenyl tetracarboxylic acid dianhydride compound with a paraphenylenediamine compound.

It is preferable that, in the dye-sensitized solar cell electrode of the present invention, the biphenyl tetracarboxylic acid dianhydride compound is 3,3′,4,4′-biphenyl tetracarboxylic acid dianhydride, and the paraphenylenediamine compound is paraphenylenediamine.

It is preferable that the dye-sensitized solar cell electrode of the present invention further includes a conductive layer formed on the surface of the substrate.

It is preferable that, in the dye-sensitized solar cell electrode of the present invention, the conductive layer is formed from at least one selected from the group consisting of gold, silver, copper, platinum, nickel, tin, tin-doped indium oxide, fluorine-doped tin oxide, and carbon.

It is preferable that, in the dye-sensitized solar cell electrode of the present invention, the conductive layer also serves as a catalyst layer, and is formed from carbon.

It is preferable that the dye-sensitized solar cell electrode of the present invention further includes a catalyst layer formed on the surface of the conductive layer.

It is preferable that, in the dye-sensitized solar cell electrode of the present invention, the catalyst layer is formed from platinum and/or carbon.

It is preferable that the dye-sensitized solar cell electrode of the present invention further includes a dye-sensitized semiconductor layer formed on the surface of the conductive layer.

It is preferable that, in the dye-sensitized solar cell electrode of the present invention, the dye-sensitized semiconductor layer is formed from a dye-sensitized semiconductor particle that is a semiconductor particle to which dye is adsorbed.

A dye-sensitized solar cell of the present invention includes a working electrode; a counter electrode that is disposed to face the working electrode with a space provided therebetween; and an electrolyte that fills in between the working electrode and the counter electrode, and contains iodine; wherein the working electrode and/or the counter electrode is the above-described dye-sensitized solar cell electrode.

The dye-sensitized solar cell electrode of the present invention ensures flexibility and a light weight, allows mass production and cost reduction, and has excellent iodine resistance. Therefore, the substrate can be prevented from being dyed with iodine, and iodine penetration of the substrate can be prevented.

Therefore, the dye-sensitized solar cell in which the dye-sensitized solar cell electrode of the present invention is used as an electrode can be used in various fields as a solar cell that allows mass production and cost reduction; and can prevent poor appearance due to iodine in the electrolyte, and further can prevent a decrease in power generation efficiency caused by penetration of and/or decomposition of substrate by iodine in the electrolyte.

### BRIEF DESCRIPTION OF THE DRAWINGS

FIG. 1 shows a cross-sectional view of an embodiment (an embodiment in which a cathode-side substrate exposing from a catalyst layer is in contact with an electrolyte) of the dye-sensitized solar cell of the present invention.

FIG. 2 shows a cross-sectional view of an embodiment (an embodiment in which a counter electrode includes a cathode-side substrate, a cathode-side conductive layer, and a catalyst layer) of the dye-sensitized solar cell electrode of the present invention.

FIG. 3 shows a cross-sectional view of another embodiment (an embodiment in which a counter electrode includes a cathode-side substrate and a cathode-side conductive layer) of the dye-sensitized solar cell electrode of the present invention.

FIG. 4 shows a cross-sectional view of another embodiment (an embodiment in which a cathode-side conductive layer is interposed between a cathode-side substrate and an electrolyte) of the dye-sensitized solar cell of the present invention.

FIG. 5 shows a cross-sectional view of another embodiment (an embodiment in which the anode-side conductive layers and cathode-side conductive layers are connected to current collecting wirings) of the dye-sensitized solar cell of the present invention.

### DETAILED DESCRIPTION OF THE INVENTION

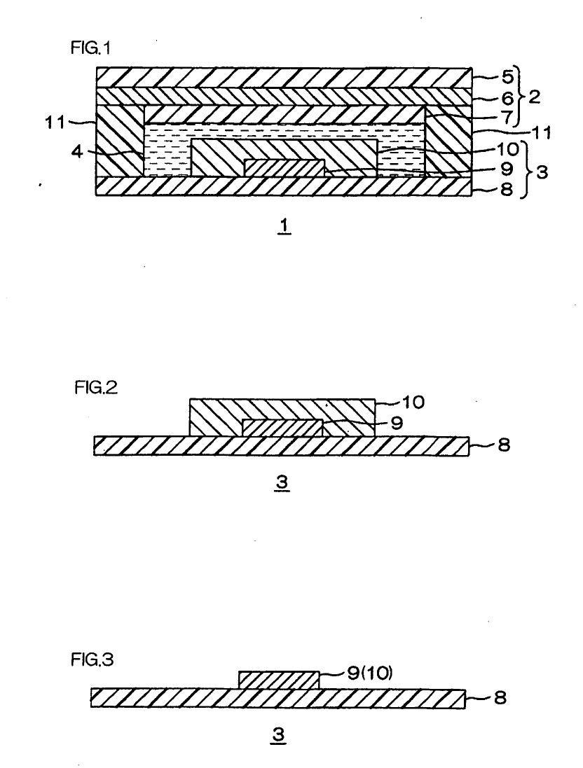

FIG. 1 shows a cross-sectional view of an embodiment (an embodiment in which a cathode-side substrate exposing from a catalyst layer is in contact with an electrolyte) of the dye-sensitized solar cell of the present invention, FIG. 2 shows a cross-sectional view of an embodiment (an embodiment in which a counter electrode includes a cathode-side substrate, a cathode-side conductive layer, and a catalyst layer) of the dye-sensitized solar cell electrode of the present invention.

In FIG. 1, a dye-sensitized solar cell 1 includes a working electrode 2 (anode); a counter electrode (cathode, opposing electrode) 3 that is disposed to face the working electrode 2 in the thickness direction of the electrodes (up/down direction in FIG. 1) with a space provided therebetween; and an electrolyte 4 that fills in between the working electrode 2 and the counter electrode 3.

The working electrode 2 has a photosensitizing function, and is formed into a generally flat plate shape. The working electrode 2 includes an anode-side substrate 5, an anode-side conductive layer 6 as a conductive layer laminated onto the lower face (facing side or surface that faces the electrolyte 4) of the anode-side substrate 5, and a dye-sensitized semiconductor layer 7 laminated onto the lower face (facing side or surface that faces the electrolyte 4) of the anode-side conductive layer 6.

The anode-side substrate 5 is transparent, and formed into a flat plate shape. For example, the anode-side substrate 5 is formed from an insulating plate or an insulating film, examples of which include a rigid plate such as a glass substrate, and a flexible film (excluding a polyimide film obtained by reaction of a specific monomer described later) such as a plastic film.

Examples of the plastic material for the plastic film include polyester resins (excluding liquid crystal polymer to be described later) such as polyethylene terephthalate (PET), polybutylene terephthalate, and polyethylene-2,6-naphthalate (PEN); liquid crystal polymers such as thermotropic liquid crystal polyester and thermotropic liquid crystal polyester amide; acrylic resins such as polyacrylate and polymethacrylate; olefin resins such as polyethylene and polypropylene; vinyl resins such as polyvinyl chloride, an ethylene-vinyl acetate copolymer, and an ethylene-vinylalcohol copolymer; imide resins such as polyimide (excluding polyimide obtained by reaction of a biphenyl tetracarboxylic acid dianhydride compound with a paraphenylenediamine compound described later) and polyamide-imide; and ether resins such as polyethernitrile and polyether sulfone. These plastic materials may be used alone, or may be used in combination of two or more.

The thickness of the anode-side substrate 5 is, for example, 5 to 500 μm, or preferably 10 to 400 μm.

The anode-side conductive layer 6 is composed of, for example, a transparent conductive thin film, and is formed on the entire lower face of the anode-side substrate 5.

Examples of the conductive materials that form the transparent conductive thin film include metal materials such as gold, silver, copper, platinum, nickel, tin, and aluminum; metal oxide (composite oxide) materials such as tin-doped indium oxide (ITO), fluorine-doped tin oxide (FTO), and zinc-doped indium oxide (IZO); and a carbon material such as carbon. These conductive materials may be used alone, or may be used in combination of two or more.

The resistivity of the anode-side conductive layer 6 is, for example, 1.0×10⁻² Ω·cm or less, or preferably 1.0×10⁻³ Ω·cm or less.

The thickness of the anode-side conductive layer 6 is, for example, 0.01 to 100 μm, or preferably 0.1 to 10 μm.

The dye-sensitized semiconductor layer 7 is formed at a widthwise (the left/right direction in FIG. 1) middle portion on the lower face of the anode-side conductive layer 6. That is, the dye-sensitized semiconductor layer 7 is formed so that both widthwise end portions of the anode-side conductive layer 6 are exposed.

The dye-sensitized semiconductor layer 7 is formed by laminating dye-sensitized semiconductor particles into a film. Such dye-sensitized semiconductor particles are, for example, porous semiconductor particles composed of metal oxide to which dye is adsorbed.

Examples of the metal oxide include titanium oxide, zinc oxide, tin oxide, tungsten oxide, zirconium oxide, hafnium oxide, strontium oxide, indium oxide, yttrium oxide, lanthanum oxide, vanadium oxide, niobium oxide, tantalum oxide, chromic oxide, molybdenum oxide, iron oxide, nickel oxide, and silver oxide. A preferable example is titanium oxide.

Examples of the dye include metal complexes such as a ruthenium complex and a cobalt complex; and organic dyes such as a cyanine dye, a merocyanine dye, a phthalocyanine dye, a coumarin dye, a riboflavin dye, a xanthene dye, a triphenylmethane dye, an azo dye, and a chinone dye. Preferable examples are a ruthenium complex and a merocyanine dye.

The average particle size of the dye-sensitized semiconductor particles is, on the primary particle size basis, for example, 5 to 200 nm, or preferably 8 to 100 nm.

The thickness of the dye-sensitized semiconductor layer 7 is, for example, 0.4 to 100 μm, preferably 0.5 to 50 μm, or more preferably 0.5 to 15 μm.

The counter electrode 3, which is to be described in detail later, is formed into a generally flat plate shape.

The electrolyte 4 is prepared, for example, as a solution (liquid electrolyte) obtained by dissolving the electrolyte in a solvent, or as a gel electrolyte obtained by gelling such a solution.

The electrolyte 4 includes, as essential components, iodine, and/or a combination of iodine and an iodine compound (redox system).

Examples of the iodine compound include metal iodides such as lithium iodide (LiI), sodium iodide (Nap, potassium iodide (KI), cesium iodide (CsI), and calcium iodide (CaI₂); and organic quaternary ammonium iodide salts such as tetraalkyl ammonium iodide, imidazolium iodide, and pyridinium iodide.

The electrolyte 4 may also include, as optional components, for example, a halogen (excluding iodine) such as bromine; or a combination of a halogen and a halogen compound (excluding a combination of iodine and an iodine compound) such as a combination of bromine and a bromine compound.

Examples of the solvent include organic solvents, and an aqueous solvent such as water. Examples of the organic solvents include carbonate compounds such as dimethyl carbonate, diethyl carbonate, methyl ethyl carbonate, ethylene carbonate, and propylene carbonate; ester compounds such as methyl acetate, methyl propionate, and gamma-butyrolactone; ether compounds such as diethylether, 1,2-dimethoxyethane, 1,3-dioxolane, tetrahydrofuran, and 2-methyl-tetrahydrofuran; heterocyclic compounds such as 3-methyl-2-oxazolidinone and 2-methylpyrrolidone; nitrile compounds such as acetonitrile, methoxyacetonitrile, propionitrile, and 3-methoxypropionitrile; and aprotic polar compounds such as sulfolane, dimethyl sulfoxide(DMSO), and N,N-dimethyl formamide. A preferable example is an organic solvent, and a more preferable example is a nitrile compound.

The proportion of the electrolyte content is, for example, 0.001 to 10 parts by weight, or preferably 0.01 to 1 part by weight relative to 100 parts by weight of the liquid electrolyte. Although it depends on the molecular weight of the electrolyte, the electrolyte concentration in the electrolyte 4 may be set to, on the normality basis, for example, 0.001 to 10M, or preferably 0.01 to 1M.

The gel electrolyte is prepared by adding, for example, a known gelling agent at an appropriate ratio into a liquid electrolyte.

Examples of the gelling agent include a low molecular weight gelling agent such as a natural higher fatty acid, amino acid compounds, and polysaccharides; and a high molecular weight gelling agent such as a fluorine-based polymer (e.g., polyvinylidene fluoride, a vinylidene fluoride-hexafluoropropylene copolymer, etc.), and a vinyl-based polymer (e.g., polyvinyl acetate, polyvinyl alcohol, etc.).

The dye-sensitized solar cell 1 is also provided with a sealing layer 11 for sealing in the electrolyte 4 between the working electrode 2 and the counter electrode 3.

The sealing layer 11 fills in between the working electrode 2 and the counter electrode 3, at both widthwise end portions of the dye-sensitized solar cell 1. The sealing layer 11 is disposed adjacent to and at both outer side faces of the dye-sensitized semiconductor layer 7.

Examples of the sealing material that forms the sealing layer 11 include a silicone resin, an epoxy resin, a polyisobutylene-based resin, a hot-melt resin, and fritted glass.

The thickness of the sealing layer 11 (the length in the up/down direction) is, for example, 5 to 500 μm, preferably 5 to 100 μm, or more preferably 10 to 50 μm.

In the dye-sensitized solar cell 1 of FIG. 1, an embodiment of the dye-sensitized solar cell electrode of the present invention (FIG. 2) is used as the counter electrode 3, and the counter electrode 3 includes a cathode-side substrate 8 as the substrate.

In FIGS. 1 and 2, the cathode-side substrate 8 is formed from a polyimide film.

The polyimide film can be obtained by reaction of a biphenyl tetracarboxylic acid dianhydride compound with a paraphenylenediamine compound.

Examples of the biphenyl tetracarboxylic acid dianhydride compound include 3,3′,4,4′-biphenyl tetracarboxylic acid dianhydride (s-BPDA), 2,3,3′,4′-biphenyl tetracarboxylic acid dianhydride (a-BPDA), and derivatives thereof.

Examples of such derivatives include halogenated biphenyl tetracarboxylic acid dianhydride such as 2,2′-difluoro-4,4′,5,5′-biphenyl tetracarboxylic acid dianhydride, 2,2′-dichloro-4,4′,5,5′-biphenyl tetracarboxylic acid dianhydride, 2,2′-dibromo-4,4′,5,5′-biphenyl tetracarboxylic acid dianhydride, and 2,2′-diiodo-4,4′,5,5′-biphenyl tetracarboxylic acid dianhydride; and halogenated alkyl-biphenyl tetracarboxylic acid dianhydride such as 2,2′-bis(trifluoromethyl)-4,4′,5,5′-biphenyl tetracarboxylic acid dianhydride, 2,2′-bis(trichloromethyl)-4,4′,5,5′-biphenyl tetracarboxylic acid dianhydride, 2,2′-bis(tribromomethyl)-4,4′,5,5′-biphenyl tetracarboxylic acid dianhydride, 2,2′-bis(triiodomethyl)-4,4′,5,5′-biphenyl tetracarboxylic acid dianhydride.

A preferable example of the biphenyl tetracarboxylic acid dianhydride compound include 3,3′,4,4′-biphenyl tetracarboxylic acid dianhydride.

The biphenyl tetracarboxylic acid dianhydride compound may be used alone, or may be used in combination of two or more.

Examples of the paraphenylenediamine compound include paraphenylenediamine (p-phenylenediamine), paraminodiphenylamine (p-aminodiphenylamine, 4-aminodiphenylamine), N,N′-bis(1-methylheptyl)-p-phenylenediamine, N,N′-bis(1-ethyl-3-methylpentyl)-p-phenylenediamine, N,N′-bis(1,4-dimethylpentyl)-p-phenylenediamine, N,N-di-β-naphthyl-p-phenylenediamine, N-o-tolyl-N′ phenyl-p-phenylenediamine, N,N-di-p-tolyl-p-phenylenediamine, N-1,3-dimethylbutyl-N′-phenyl-p-phenylenediamine, N-1,4-dimethylpentyl-N′-phenyl-p-phenylenediamine, N-isopropyl-N′-phenyl-p-phenylenediamine, N-1-methylpropyl-N′-phenyl-p-phenylenediamine, N-cyclohexyl-N′-phenyl-p-phenylenediamine, N,N′-bis-(1-ethyl-3-methylpentyl)-p-phenylenediamine, N,N′-bis-(1,4-dimethylpentyl)-p-phenylenediamine, N,N′-bis-(1-methylpropyl)-p-phenylenediamine, N-phenyl-N′-(1,3-dimethylbutyl)-p-phenylenediamine, N-phenyl-N′-isopropyl-p-phenylenediamine, N-phenyl-N′-(1-methylheptyl)-p-phenylenediamine, N-phenyl-N′-cyclohexyl-p-phenylenediamine, and N-phenyl-N′-p-toluenesulfonyl-p-phenylenediamine.

A preferable example is paraphenylenediamine.

The paraphenylenediamine compound may be used alone, or may be used in combination of two or more.

In the reaction of the biphenyl tetracarboxylic acid dianhydride compound with the paraphenylenediamine compound, for example, first, the above-described components (monomers) are blended and subjected to polycondensation, thereby preparing polyamic acid (polyamide acid, or a precursor of polyimide), and afterwards, the polyamic acid is imidized (cured).

To obtain polyamic acid, first, a monomer solution is prepared by mixing the biphenyl tetracarboxylic acid dianhydride compound and the paraphenylenediamine compound at a substantially equal molar ratio, as necessary, in an appropriate organic solvent.

Examples of the organic solvent include polar solvents such as N-methyl-2-pyrrolidone (NMP), N,N-dimethylacetamide, N,N-dimethylformamide (DMF), dimethylsulfoxide (DMSO), and hexamethylphosphoramide.

The mixing ratio of the polar solvent is adjusted so that the concentration of the polyamic acid to be obtained is, for example, 5 to 50 wt %, or preferably 10 to 25 wt %.

The monomer solution can be prepared by stirring the above-described monomers, for example, at 25 to 80° C. for 5 to 48 hours.

Polycondensation of the biphenyl tetracarboxylic acid dianhydride compound with the paraphenylenediamine compound is performed, for example, by heating the monomer solution at 0 to 80° C. for 1 to 48 hours. Varnish (solution of polyamic acid) can be obtained in this manner.

Afterwards, to imidize polyamic acid, the obtained varnish is molded into a film, and then the film is heated and cured.

Examples of the film molding method include casting and extrusion molding.

In casting, for example, varnish is applied on a base material, and then dried.

Examples of the base material include a metal foil and a metal plate. The metal foil or the metal plate is formed, for example, from copper, copper alloy, nickel, nickel alloy, nickel/iron alloy, iron, stainless steel, aluminum, copper-beryllium, phosphor bronze, or the like.

For the application, a known application method such as spin coating, bar coating, or the like is used.

For the drying, for example, heating is carried out at 80 to 150° C., or preferably 90 to 120° C.

In extrusion molding, for example, a film is molded using a known extruder having a gear pump, a head (mouthpiece), and the like, and dried.

Furthermore, in extrusion molding, the film extruded from the head can be stretched by tentering, and in such a case, the extruded film is stretched, for example, 1.1 to 2.5 times in the stretch direction (running direction), and for example, 0.5 to 2.0 times in the width direction (direction perpendicular to the stretch direction).

The temperature for the heating and curing is, for example, 250 to 500° C., or preferably 350 to 450° C.

By such heating and curing, polyamic acid is imidized, thereby forming the cathode-side substrate 8 made of a polyimide film.

As such a polyimide film, commercially available polyimide films may be used, such as, for example, Upilex® S series (manufactured by Ube Industries, Ltd.).

The polyimide film has a degree of crystallinity of, for example, 50% or more, preferably 60% or more, or more preferably 65% or more; and usually 90% or less. The degree of crystallinity of the polyimide film is determined by X-ray diffraction.

When the degree of crystallinity is in the above-described range, excellent iodine resistance can be obtained.

The polyimide film has a water absorption (ASTM D570) of, when immersed in water having a temperature of 23° C. for 24 hours, for example, 5 wt % or less, or preferably 3 wt % or less; and usually 0.03 wt % or more.

The polyimide film has a weight change rate in the iodine resistance test to be described later of, for example, 10 wt % or less, preferably 5 wt % or less, more preferably 1 wt % or less, or even more preferably 0.5 wt % or less; and usually 0.01 wt % or more. In the iodine resistance test to be described later, the polyimide film has an iodine content of, for example, 3000 (μg iodine/g) or less, preferably 1000 (μg iodine/g) or less, or more preferably 300 (μg iodine/g) or less; and usually 10 (μg iodine/g) or more.

The thickness of the cathode-side substrate 8 is, for example, 5 to 500 μm, preferably 8 to 100 μm, or more preferably 12 to 50 μm. When the thickness of the cathode-side substrate 8 is below the above-described range, workability may be reduced, and when the thickness of the cathode-side substrate 8 exceeds the above-described range, costs may increase.

The counter electrode 3 further includes, to be specific, a cathode-side conductive layer 9 as the conductive layer, and a catalyst layer 10.

The cathode-side conductive layer 9 is formed on the upper face (facing side or surface that faces the electrolyte 4) of the cathode-side substrate 8. To be specific, the cathode-side conductive layer 9 is made of a conductive thin film, and is formed at a widthwise middle portion (center portion) of the upper face of the cathode-side substrate 8. To be specific, the cathode-side conductive layer 9 is included in the dye-sensitized semiconductor layer 7 when projected in the thickness direction thereof, and is formed so that both widthwise end portions of the cathode-side substrate 8 are exposed.

Examples of the conductive material that forms the cathode-side conductive layer 9 include the abovementioned conductive materials that form the anode-side conductive layer 6. Preferable examples are gold, silver, copper, platinum, nickel, tin, ITO, FTO, and carbon. Such conductive materials are advantageous in that electrons are efficiently released and received.

These conductive materials may be used alone, or may be used in combination of two or more.

The resistivity of the cathode-side conductive layer 9 is, for example, 1.0×10⁻² Ω·cm or less, preferably 1.0×10⁻³ Ω·cm or less, or more preferably 1.0×10⁻⁵ Ω·cm or less.

The thickness of the cathode-side conductive layer 9 is, for example, 0.1 to 100 μm, or preferably 1 to 50 μm. When the thickness of the cathode-side conductive layer 9 is below the above-described range, the conductivity may decrease excessively (the resistivity increases excessively), and when the thickness of the cathode-side conductive layer 9 is above the above-described range, costs may increase and it may become difficult to achieve a thin product.

The catalyst layer 10 is formed on the upper face (facing side or surface that faces the electrolyte 4) of the cathode-side conductive layer 9. To be specific, the catalyst layer 10 is formed on the cathode-side substrate 8, so as to cover the surface (upper face and both widthwise side faces) of the cathode-side conductive layer 9.

The catalyst layer 10 is included in the dye-sensitized semiconductor layer 7 when projected in the thickness direction thereof, and one widthwise side face of the catalyst layer 10 is positioned between one widthwise side face of the dye-sensitized semiconductor layer 7 and one widthwise side face of the cathode-side conductive layer 9. The other widthwise side face of the catalyst layer 10 is positioned between the other widthwise side face of the dye-sensitized semiconductor layer 7 and the other widthwise side face of the cathode-side conductive layer 9.

Examples of the material that forms the catalyst layer 10 include noble metal materials such as platinum, ruthenium, and rhodium; conductive organic materials such as polydioxythiophene and polypyrrole; and a carbon material such as carbon. Preferable examples are platinum and carbon. Such materials are advantageous in that electrons are efficiently released and received.

These materials may be used alone, or may be used in combination of two or more.

The thickness of the catalyst layer 10 is, for example, 50 nm to 100 μm, or preferably 100 nm to 50 μm. When the thickness of the catalyst layer 10 is below the above-described range, in the electrolyte 4, acceleration of oxidation-reduction reaction by electrolyte may not be achieved sufficiently, and power generation efficiency may decrease. When the thickness of the catalyst layer 10 exceeds the above-described range, costs may increase.

To produce the dye-sensitized solar cell 1, first, the working electrode 2, the counter electrode 3, and the electrolyte 4 are prepared (or made).

The working electrode 2 is made by sequentially laminating the anode-side substrate 5, the anode-side conductive layer 6, and the dye-sensitized semiconductor layer 7 downward in the thickness direction.

The electrolyte 4 is prepared as the above-described liquid electrolyte or a gelled electrolyte.

To produce the counter electrode 3, first, the cathode-side substrate 8 is prepared.

Next, as necessary, a surface treatment is given to the upper face of the cathode-side substrate 8 by a plasma treatment or a physical vapor deposition method. Such surface treatments may be given singly or in combination of two or more.

Examples of the plasma treatment include a nitrogen plasma treatment. Conditions of the nitrogen plasma treatment are noted below.

Pressure (reduced pressure): 0.01 to 100 Pa, or preferably 0.05 to 10 Pa

Flow rate of nitrogen introduced: 10 to 1000 SCCM (standard cc/min), or preferably 10 to 300 SCCM

Treatment temperature: 0 to 150° C., or preferably 0 to 120° C.

Electric power: 30 to 1800 W, or preferably 150 to 1200 W

Treatment time: 0.1 to 30 minutes, or preferably 0.15 to 10 minutes

The nitrogen plasma treatment causes the upper face of the cathode-side substrate 8 to be nitrogenized.

Examples of the physical vapor deposition method include vacuum deposition, ion plating, and sputtering. A preferable example is sputtering.

Examples of the sputtering include a metal sputtering using metals such as nickel or chromium as a target. By metal sputtering, a metal thin film (not shown) is formed on the upper face of the cathode-side substrate 8. The thickness of the metal thin film is, for example, 1 to 1000 nm, or preferably 10 to 500 nm.

The above-described surface treatment allows an improvement in adhesion of the cathode-side conductive layer 9 to the cathode-side substrate 8.

Next, the cathode-side conductive layer 9 is formed on the cathode-side substrate 8.

The cathode-side conductive layer 9 is formed, for example, by a printing method, a spraying method, a physical vapor deposition method, an additive method, or a subtractive method, into the above-described pattern.

In the printing method, for example, a paste containing microparticles of the above-described conductive material is screen printed on the upper face of the cathode-side substrate 8, into the above-described pattern.

In the spraying method, for example, a dispersion of the above-described conductive material microparticles dispersed in a known dispersion medium is prepared first. Also, a mask having a predetermined pattern of opening is used to cover the upper face of the cathode-side substrate 8. Afterwards, from above the cathode-side substrate 8 and the mask, the prepared dispersion is blown (sprayed). Afterwards, the mask is removed and the dispersion medium is evaporated.

As the physical vapor deposition method, sputtering is preferably used. To be specific, after covering the upper face of the cathode-side substrate 8 with a mask having a predetermined pattern of opening, sputtering is performed using, for example, metal materials or metal oxide materials as a target, and then the mask is removed.

In the additive method, for example, a thin conductive film (seed film), which is not shown, is formed first on the upper face of the cathode-side substrate 8. As the thin conductive film, a chromium thin film is laminated by sputtering, or preferably by chromium sputtering. When the metal thin film is already formed by the above-described surface treatment (physical vapor deposition method), the surface treatment for the cathode-side substrate 8 can also serve as the formation of the thin conductive film.

Then, after forming a plating resist having a reverse pattern to the above-described pattern on the upper face of the thin conductive film, the cathode-side conductive layer 9 is formed on the upper face of the thin conductive film exposing from the plating resist by electrolytic plating. Afterwards, the plating resist and the portion of the thin conductive film where the plating resist was laminated are removed.

In the subtractive method, for example, a two-layer substrate (copper-clad two-layer substrate, etc.) obtained by laminating a conductive foil composed of the above-described conductive material onto the upper face of the cathode-side substrate 8 in advance is prepared first, and after a dry film resist is laminated onto the conductive foil, the dry film resist is exposed to light and developed so that an etching resist having the same pattern as that of the above-described cathode-side conductive layer 9 is formed. Afterwards, the conductive foil exposing from the etching resist is subjected to a chemical etching using an etching solution such as an aqueous solution of ferric chloride, and then the etching resist is removed.

For the preparation of the two-layer substrate, a conductive foil may be bonded to the upper face of the cathode-side substrate 8 by heat-fusing, or a known adhesive layer may be interposed between the cathode-side substrate 8 and the conductive foil.

In the above-described formation of the cathode-side conductive layer 9 by the subtractive method, commercially available products may be used as the copper-clad two-layer base material, including, for example, Upisel® N series (manufactured by Ube Industries, Ltd.) as a polyimide copper-clad laminate obtained by laminating copper foil onto the upper face of a polyimide film in advance.

Then, the catalyst layer 10 is formed on the cathode-side substrate 8 so as to cover the cathode-side conductive layer 9.

The catalyst layer 10 is formed, for example, by a known method such as a printing method, a spraying method, or a physical vapor deposition method, into the above-described pattern. The printing method, the spraying method, and the physical vapor deposition method can be performed according to the above-described method.

Preferably, when the catalyst layer 10 is to be formed from a noble metal, a physical vapor deposition method (e.g., vacuum deposition, sputtering, etc.) is used; and when the catalyst layer 10 is to be formed from a conductive organic compound or a carbon material, a printing method or a spraying method is used.

The counter electrode 3 is made in this manner.

Then, the working electrode 2 and the counter electrode 3 are disposed to face each other so that the dye-sensitized semiconductor layer 7 and the catalyst layer 10 are adjacent to each other, with a space for providing the sealing layer 11 therebetween. At the same time, the sealing layer 11 is provided on one widthwise side of the working electrode 2 and the counter electrode 3, and after pouring in the electrolyte 4 between the working electrode 2 and the counter electrode 3, the sealing layer 11 is further provided on the other widthwise side of the working electrode 2 and the counter electrode 3, thus sealing in the electrolyte 4.

Although not shown in the drawings, upon providing the sealing layer 11, the sealing layers 11 are provided also at both anteroposterior (direction perpendicular to the width direction and the thickness direction) sides so as to seal in the electrolyte 4.

The dye-sensitized solar cell 1 can be produced in this manner.

In the dye-sensitized solar cell 1 thus obtained, the counter electrode 3 includes the cathode-side substrate 8 made of the above-described polyimide film, and therefore flexibility and a light weight can be ensured, and mass production and low-cost can be achieved.

Furthermore, the cathode-side substrate 8 in the counter electrode 3 is made of the above-described polyimide film, and therefore a high degree of crystallinity can be ensured, and iodine resistance is excellent. Therefore, the cathode-side substrate 8 can be prevented from being dyed with iodine, and the cathode-side substrate 8 can also be prevented from being penetrated by iodine, and at the same time, decomposition of the cathode-side substrate 8 by iodine can be suppressed.

Additionally, excellent appearance can be ensured.

Thus, the dye-sensitized solar cell 1 in which the above-described counter electrode 3 is used can be used in various fields as a solar cell that allows mass production and low-cost; and can prevent poor appearance due to iodine in the electrolyte 4, and further a decrease in power generation efficiency caused by penetration and/or decomposition of the cathode-side substrate 8 by iodine in the electrolyte 4.

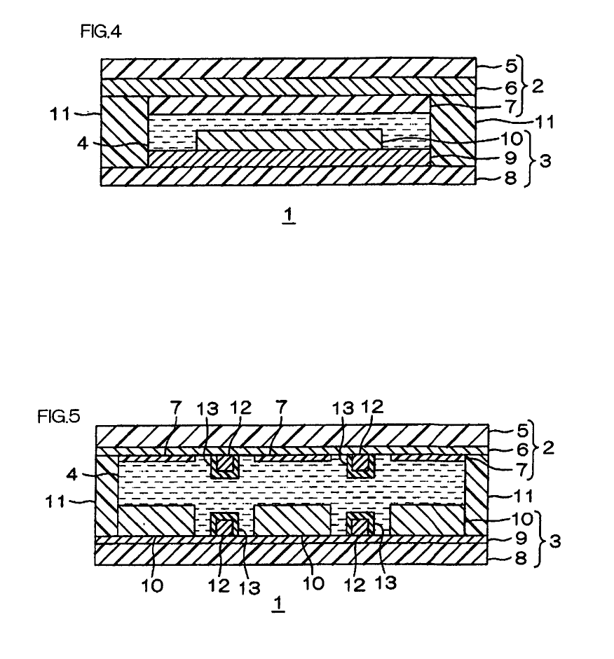

FIG. 3 shows a cross-sectional view of another embodiment (embodiment in which a counter electrode includes a cathode-side substrate and a cathode-side conductive layer) of the dye-sensitized solar cell electrode of the present invention; FIG. 4 shows a cross-sectional view of another embodiment (embodiment in which a cathode-side conductive layer is interposed between a cathode-side substrate and an electrolyte) of the dye-sensitized solar cell of the present invention; and FIG. 5 shows a cross-sectional view of another embodiment (embodiment in which an anode-side conductive layer and a cathode-side conductive layer are connected to current collecting wirings) of the dye-sensitized solar cell electrode of the present invention.

In FIG. 3 to FIG. 5, the same reference numerals are used for members corresponding to the above-described members, and detailed descriptions thereof are omitted.

Although the catalyst layer 10 is provided in the dye-sensitized solar cell electrode 3 in the above description, for example, as shown in FIG. 3, the dye-sensitized solar cell electrode 3 may be formed from the cathode-side substrate 8 and the cathode-side conductive layer 9, without using the catalyst layer 10.

The cathode-side conductive layer 9 may also serve as the catalyst layer 10. In such a case, the cathode-side conductive layer 9 is preferably formed from a carbon material such as carbon.

Although the portion of the upper face of the cathode-side substrate 8 exposing from the cathode-side conductive layer 9, the catalyst layer 10, and the sealing layer 11 is in contact with the electrolyte 4 in the above description, for example, as shown in FIG. 4, by forming the cathode-side conductive layer 9 so as to bring both widthwise side faces of the cathode-side conductive layer 9 into contact with inner side faces of the sealing layer 11, the entirety of the upper face of the cathode-side substrate 8 can be covered with the cathode-side conductive layer 9 and the sealing layers 11.

In FIG. 4, the cathode-side conductive layer 9 is formed, so as to extend between the sealing layers 11 in the widthwise direction. That is, when the cathode-side conductive layer 9 is projected in the thickness direction thereof, position of the both widthwise side faces thereof coincides with the position of the both widthwise side faces of the dye-sensitized semiconductor layer 7. That is, the cathode-side conductive layer 9 is interposed between the cathode-side substrate 8, and the electrolyte 4 and catalyst layer 10.

The catalyst layer 10 is formed at a widthwise middle portion (center portion) of the upper face of the cathode-side conductive layer 9. That is, both widthwise end portions of the upper face of the cathode-side conductive layer 9 are exposed from the catalyst layer 10.

In the dye-sensitized solar cell 1, because the cathode-side conductive layer 9 is interposed between the cathode-side substrate 8 and the electrolyte 4, the electrolyte 4 does not directly contact the cathode-side substrate 8, and therefore direct penetration of the cathode-side substrate 8 by iodine in the electrolyte 4 can be prevented.

However, when the cathode-side conductive layer 9 is formed from, for example, ITO, iodine in the electrolyte 4 may penetrate the cathode-side conductive layer 9 and reach the cathode-side substrate 8. In such a case as well, because the cathode-side substrate 8 in the counter electrode 3 of the dye-sensitized solar cell 1 is excellent in iodine resistance, the cathode-side substrate 8 can be effectively prevented from being dyed with iodine, and the cathode-side substrate 8 can also be effectively prevented from being penetrated by iodine, and at the same time, decomposition of the cathode-side substrate 8 by iodine can be effectively suppressed.

It is also possible, as shown in FIG. 5, to provide a plurality of dye-sensitized semiconductor layers 7 and catalyst layers 10 along the width direction, and also current collecting wirings 12 in therebetween.

Each of the plurality of dye-sensitized semiconductor layers 7 and each of the plurality of catalyst layers 10 are aligned in the width direction thereof with a space therebetween, and are at matching positions when the each of the plurality of dye-sensitized semiconductor layers 7 and the each of the plurality of catalyst layers 10 are projected in the thickness direction thereof.

In the working electrode 2, the plurality of current collecting wirings 12 are formed between the each of the plurality of dye-sensitized semiconductor layers 7 at the lower face of the anode-side conductive layer 6, and each of the plurality of current collecting wirings 12 is disposed in the width direction thereof with a space between the each of the plurality of current collecting wirings 12 and the each of the plurality of dye-sensitized semiconductor layers 7. The current collecting wirings 12 in the working electrode 2 are electrically connected to the anode-side conductive layer 6.

In the counter electrode 3, the plurality of current collecting wirings 12 are formed between the each of the catalyst layers 10 on the upper face of the cathode-side conductive layer 9, and the each of the current collecting wirings 12 is disposed in the width direction thereof with a space between the each of the current collecting wirings 12 and the each of the catalyst layers 10. The current collecting wirings 12 in the counter electrode 3 are electrically connected to the cathode-side conductive layer 9.

As conductive materials for forming the current collecting wirings 12, those conductive materials as described above may be used. The thickness of the current collecting wirings 12 is, for example, 0.5 to 50 μm, or preferably 0.5 to 20 μm.

On the surface of the current collecting wirings 12, a protection layer 13 is formed for preventing corrosion of the current collecting wirings 12 by the electrolyte 4.

Examples of the material for forming the protection layer 13 include resin materials such as epoxy resin and acrylic resin, and metal materials such as nickel and gold. The thickness of the protection layer 13 is, for example, 0.5 to 30 μm.

In such dye-sensitized solar cells 1, power generation efficiency can be improved by collecting electric currents of the plurality of anode-side conductive layers 6 and of the cathode-side conductive layers 9 with the plurality of current collecting wirings 12.

In the description above, of the substrates (the anode-side substrate 5 and the cathode-side substrate 8) in the working electrode 2 and the counter electrode 3 of the dye-sensitized solar cell 1, only the cathode-side substrate 8 is formed from the polyimide film. However, for example, both of the anode-side substrate 5 and the cathode-side substrate 8 can be formed from the polyimide film.

It is also possible to form the anode-side substrate 5 from a polyimide film, while forming the cathode-side substrate 8 from the above-described glass substrate or plastic film.

### EXAMPLES

### Example 1

A monomer solution was prepared by dissolving 3,3′,4,4′-biphenyl tetracarboxylic acid dianhydride and paraphenylenediamine in N,N-dimethylacetamide at an equal molar ratio so as to achieve a polyamic acid concentration of 20 wt %. Then, a solution of polyamic acid (varnish) was prepared by allowing the monomer solution to react at ambient temperature for 24 hours.

Afterwards, the prepared varnish was applied on a base material made of stainless steel, and then dried at 105° C., thereby forming a film.

Afterwards, the film was heated and cured at 375° C. A polyimide film (thickness 25 μm) was obtained in this manner. The polyimide film had a water absorption (ASTM D570) of, when immersed in water having a temperature of 23° C. for 24 hours, 1.4 wt %.

The obtained polyimide film served as a cathode-side substrate.

Then, the upper face of the cathode-side substrate was subjected to a nitriding treatment by a nitrogen plasma treatment. Conditions of the nitrogen plasma treatment are noted below.

Pressure (reduced pressure): 1.2 Pa

Flow rate of nitrogen introduced: 70 SCCM

Treatment Temperature: 21° C.

Electric Power: 200 W

Treatment Time: 0.5 minutes

Then, a cathode-side conductive layer composed of copper was formed into the above-described pattern by an additive method (ref. FIG. 2).

That is, a thin conductive film composed of a chromium thin film having a thickness of 100 nm was formed first on the upper face of the cathode-side substrate by chromium sputtering. Then, after a plating resist was formed on the upper face of the thin conductive film in a pattern reverse to the above-described pattern, a cathode-side conductive layer having a thickness of 18 μm was formed on the surface of the thin conductive film exposing from the plating resist by electrolytic copper plating. Afterwards, the plating resist and the portion of the thin conductive film where the plating resist was laminated were removed. The cathode-side conductive layer had a resistivity of 1.76×10⁻⁶ Ω·cm.

Afterwards, a catalyst layer composed of platinum was formed on the cathode-side substrate in a pattern covering the surface of the cathode-side conductive layer.

That is, after covering the upper face of the cathode-side substrate and the cathode-side conductive layer with a mask having the above-described predetermined pattern of openings, a catalyst layer having a thickness of 300 nm was formed by platinum vacuum deposition (ref. FIG. 2). Afterwards, the mask was removed.

The counter electrode (dye-sensitized solar cell electrode) shown in FIG. 2 was made in this manner.

### Example 2

A counter electrode (dye-sensitized solar cell electrode) was made in the same manner as in Example 1, except that a polyimide film (Upilex® S, thickness 25 μm, manufactured by Kaneka Corporation) was used in the preparation of the cathode-side substrate instead of the above-described polyimide film (thickness 25 μm).

This polyimide film (Upilex® S) was obtained by reaction of 3,3′,4,4′-biphenyl tetracarboxylic acid dianhydride with paraphenylenediamine.

This polyimide film (Upilex® S) had a water absorption (ASTM D570) of, when immersed in water having a temperature of 23° C. for 24 hours, 1.4 wt %.

### Comparative Example 1

A counter electrode (dye-sensitized solar cell electrode) was made in the same manner as in Example 1, except that a polyimide film (Apical® NPI, thickness 25 μm, manufactured by Kaneka Corporation) was used in the preparation of the cathode-side substrate instead of the polyimide film (thickness 25 μm).

This polyimide film (Apical® NPI) was obtained by reaction of pyromellitic acid with 4,4′-diaminophenylether.

This polyimide film (Apical® NPI) had a water absorption (ASTM D570) of, when immersed in water having a temperature of 23° C. for 24 hours, 1.7 wt %.

### Comparative Example 2

A counter electrode (dye-sensitized solar cell electrode) was made in the same manner as in Example 1, except that a polyimide film (Kapton® V, thickness 25 μm, manufactured by DU PONT-TORAY CO., LTD.) was used in the preparation of the cathode-side substrate instead of the polyimide film (thickness 25 μm).

This polyimide film (Kapton® V) was obtained by reaction of pyromellitic acid with 4,4′-diaminophenylether.

This polyimide film (Kapton® V) had a water absorption (ASTM D570) of, when immersed in water having a temperature of 23° C. for 24 hours, 2.9 wt %.

### Comparative Example 3

A counter electrode (dye-sensitized solar cell electrode) was made in the same manner as in Example 1, except that a polyethylene naphthalate film (Teonex® Q51, PEN film, thickness 25 μm, manufactured by Teijin DuPont Films Japan Limited) was used in the preparation of the cathode-side substrate instead of the polyimide film (thickness 25 μm).

This polyethylene naphthalate film (Teonex® Q51) had a water absorption (ASTM D570) of, when immersed in water having a temperature of 23° C. for 24 hours, 0.3 wt %.

### Evaluation

### (Degree of Crystallinity)

The degree of crystallinity of the cathode-side substrate of Examples and Comparative Examples was measured by X-ray diffraction.

That is, for X-ray diffraction, an X-ray diffraction device (D8-Discover with GADDS, manufactured by Bruker Axs) was used, and a two-dimensional X-ray diffraction pattern of a blank (air) and a cathode-side substrate was measured. Afterwards, the diffraction pattern of the blank substrate was deducted from the blank pattern to unify the diffraction pattern, and then the degree of crystallinity was calculated based on the area of the crystallized portion and the area of the non-crystallized portion using the following formula.

The degree of crystallinity=(area of crystallized portion)/[(area of crystallized portion)+(area of non-crystallized portion)]×100

The results are shown in Table 1.

### (Iodine Resistance Test)

The dye-sensitized solar cell electrodes obtained in Examples and Comparative Examples were immersed in a liquid electrolyte (electrolyte: iodine, normality: 0.1 M, solvent: 3-methoxypropionitrile), and allowed to stand at 80° C. for one week.

### 1) Weight Change Rate

The weight change rate (increase rate, wt %) of the dye-sensitized solar cell electrode before and after the above-described iodine resistance test was measured. The results are shown in Table 1.

### 2) Iodine Content

The iodine content of the liquid electrolyte before and after the iodine resistance test was measured using an ion chromatograph. Afterwards, by deducting the iodine content in the liquid electrolyte after the iodine resistance test from the iodine content in the liquid electrolyte before the iodine resistance test, the iodine content of the dye-sensitized solar cell electrode was calculated. The results are shown in Table 1.

### 3) Appearance

Presence or absence of dyeing of the cathode-side substrate of the dye-sensitized solar cell electrode before and after the above-described iodine resistance test was checked visually. The results are shown in Table 1. Details of the abbreviations in Table 1 are noted below.

NO: It was not confirmed that the cathode-side substrate was dyed with iodine.

YES: It was confirmed that the cathode-side substrate was dyed with iodine.

TABLE 1

| | | | Cathode-side substrate | | Counter Electrode | | |
|---|---|---|---|---|---|---|---|
| | | | | Water Absorption | Iodine Resistance Test | | |
| | | | | (%) | Weight | Iodine | |
| Ex. and | | | Degree of | Immersed in Water | Change Rate | Content | |
| Comp. | Materials for Cathode-Side Substrate | | Crystallinity | of 23° C. | [increase | (μg | Appearance |
| Ex. | | Monomer | (%) | for 24 hours | rate] (wt %) | iodine/g) | Change |
| Ex. 1 | Polyimide | 3,3′,4,4′-biphenyl | 55 | 1.4 | +0.5 | 210 | NO |
| | | tetracarboxylic acid | | | | | |
| | | dianhydride and | | | | | |
| | | paraphenylene | | | | | |
| | | diamine | | | | | |
| Ex. 2 | Polyimide | 3,3′,4,4′-biphenyl | 68 | 1.4 | +0.2 | 131 | NO |
| | (Upilex ® S) | tetracarboxylic acid | | | | | |
| | | dianhydride and | | | | | |
| | | paraphenylenediamine | | | | | |
| Comp. | Polyimide | Pyromellitic acid | 40 | 1.7 | +14.8 | 4460 | YES |
| Ex. 1 | (Apical ® | and 4,4′- | | | | | |
| | NPI) | diaminophenylether | | | | | |
| Comp. | Polyimide | Pyromellitic acid | 61 | 2.9 | +13.5 | 3150 | YES |
| Ex. 2 | (Kapton ® V) | and 4,4′- | | | | | |
| | | diaminophenylether | | | | | |

| | | | | | | |
|---|---|---|---|---|---|---|
| Comp. | Polyethylene naphthalate | 74 | 0.3 | 2.5 | 1100 | YES |
| Ex. 3 | (Teonex © Q51) | | | | | |

While the illustrative embodiments of the present invention are provided in the above description, such is for illustrative purpose only and it is not to be construed as limiting the scope of the present invention. Modification and variation of the present invention that will be obvious to those skilled in the art is to be covered by the following claims.

What is claimed is:

1. A dye-sensitized solar cell electrode comprising a substrate made of a polyimide film obtained by reaction of a biphenyl tetracarboxylic acid dianhydride compound with a paraphenylenediamine compound.

2. The dye-sensitized solar cell electrode according to claim 1, wherein the biphenyl tetracarboxylic acid dianhydride compound is 3,3′,4,4′-biphenyl tetracarboxylic acid dianhydride, and the paraphenylenediamine compound is paraphenylenediamine.

3. The dye-sensitized solar cell electrode according to claim 1, further comprising a conductive layer formed on the surface of the substrate.

4. The dye-sensitized solar cell electrode according to claim 3, wherein the conductive layer is formed from at least one selected from the group consisting of gold, silver, copper, platinum, nickel, tin, tin-doped indium oxide, fluorine-doped tin oxide, and carbon.

5. The dye-sensitized solar cell electrode according to claim 3, wherein the conductive layer also serves as a catalyst layer.

6. The dye-sensitized solar cell electrode according to claim 5, wherein the conductive layer is formed from carbon.

7. The dye-sensitized solar cell electrode according to claim 3, further comprising a catalyst layer formed on the surface of the conductive layer.

8. The dye-sensitized solar cell electrode according to claim 7, wherein the catalyst layer is formed from platinum and/or carbon.

9. The dye-sensitized solar cell electrode according to claim 3, further comprising a dye-sensitized semi conductor layer formed on the surface of the conductive layer.

10. The dye-sensitized solar cell electrode according to claim 9, wherein the dye-sensitized semiconductor layer is formed from a dye-sensitized semiconductor particle that is a semiconductor particle to which dye is adsorbed.

11. A dye-sensitized solar cell comprising:
a working electrode,
a counter electrode that is disposed to face the working electrode with a space provided therebetween, and
an electrolyte that fills in between the working electrode and the counter electrode, and contains iodine,
wherein the working electrode and/or the counter electrode is a dye-sensitized solar cell electrode comprising a substrate made of a polyimide film obtained by reaction of a biphenyl tetracarboxylic acid dianhydride compound with a paraphenylenediamine compound.
